(19) United States
(12) Patent Application Publication
(10) Pub. No.: US 2007/0243670 A1
(43) Pub. Date: Oct. 18, 2007

(54) Thin Film Transistor (TFT) and Method for Fabricating the Same

(75) Inventors: Chi-Lin Chen, Hsinchu (TW); Po-Hao Tsai, Hsinchu (TW); Hung-Tse Chen, Hsinchu (TW); Yu-Cheng Chen, Hsinchu (TW); Jia-Xing Lin, Hsinchu (TW)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Industrial Technology Research Institute, Hsinchu (TW)

(21) Appl. No.: 11/279,933

(22) Filed: Apr. 17, 2006

(51) Int. Cl. H01L 21/84; H01L 21/20

(52) U.S. Cl. 438/149; 438/486; 257/E29.151; 257/E21.133

(57) ABSTRACT

A method for fabricating a thin film transistor (“TFT”) device includes providing a substrate, forming a patterned amorphous silicon layer over the substrate including a pair of first regions, a second region disposed between the pair of first regions, and at least one third region, each of which being disposed between and contiguous with the second region and each of the pair of first regions, the second region including a sub-region contiguous with each of the at least one third region, forming a heat retaining layer over the substrate, irradiating the patterned amorphous silicon layer with a laser through the heat retaining layer to form a patterned crystallized silicon layer corresponding to the patterned amorphous silicon layer including a grain boundary extending substantially across a crystallized sub-region corresponding to the sub-region, and forming a patterned conductive layer over a portion of a crystallized second region of the patterned crystallized silicon layer corresponding to the second region of the patterned amorphous silicon layer.

### BACKGROUND OF THE INVENTION

The present invention relates generally to semiconductor manufacturing, and more particularly, to a thin film transistor (“TFT”) and a method of fabricating the same.

Polycrystalline silicon thin film as a high quality active layer in semiconductor devices has recently attracted considerable attention due to its superior charge carrier transport property and high compatibility with current semiconductor device fabrication. With low temperature process, it is possible to fabricate reliable polycrystalline silicon thin film transistors (“TFTs”) on transparent glass or plastic substrates for making polycrystalline silicon more competitive in the application of large area flat panel displays such as active matrix liquid crystal displays (“AMLCDs”) or active matrix organic light emitting diode displays (“OLEDs”).

The importance of polycrystalline silicon TFTs comprises a superior display performance such as high pixel aperture ratio, low driving power consumption, high device reliability, and among others, an enabling feature of integrating various peripheral driver components directly onto the glass substrate. Peripheral circuit integration is not only beneficial in reducing the running cost, but also in enriching the functionality for mobile purpose applications. However, the device performance of polycrystalline silicon TFTs, such as carrier mobility, is significantly affected by the crystal grain size. The carrier flow in an active channel has to overcome the energy barrier of the grain boundary between each crystal grain, and thus the carrier mobility decreases. Therefore, in order to improve the device performance, it is very important to reduce the number of polycrystalline silicon grain boundaries within the active channel. To fulfill the requirement, grain size enlargement and grain boundary location control within the active channel are the two possible manipulations.

Conventional methods for fabricating polycrystalline silicon thin film comprise solid phase crystallization (“SPC”) and direct chemical vapor phase deposition (“CVD”). These techniques are not applicable to high performance flat panel displays because the crystalline quality is limited by the low process temperature (typically lower than 650° C.) and the grain size of polycrystalline silicon thus fabricated is as small as 100 nm (nanometer). Hence, the electrical characteristics of polycrystalline silicon thin films are limited.

The excimer laser annealing (“ELA”) method is currently the most commonly used method in polycrystalline silicon TFT fabrication. The grain size of polycrystalline silicon thin film can reach 300-600 nm, and the carrier mobility of polycrystalline silicon TFTs can reach 200 cm²/V-s. However, this value is yet not sufficient for future demand of high performance flat panel displays. Furthermore, unstable laser energy output of ELA narrows down the process window generally to several tens of mJ/cm². As a result, frequently repeated laser irradiation is necessary to re-melt imperfect fine grains caused by the irregular laser energy fluctuation. The repeated laser irradiation may render ELA less competitive due to its high cost in process optimization and system maintenance.

Although a few methods for enlarging grain size of polycrystalline silicon have been set forth recently, these methods such as sequential lateral solidification (“SLS”) and phase modulated ELA (“PMELA”) all still require additional modification and further process parameter control for the current ELA systems. It is therefore desirable to have a method of semiconductor thin film crystallization that can achieve greater, uniform grain size and a precise control of grain boundary in a cost efficient manner without compromising desired electrical properties.

### BRIEF SUMMARY OF THE INVENTION

The present invention is directed to a thin film transistor (“TFT”) and a method for fabricating the same that obviate one or more problems resulting from the limitations and disadvantages of the prior art.

In accordance with an embodiment of the present invention, there is provided a method for fabricating a thin film transistor (“TFT”) device that comprises providing a substrate, forming a patterned amorphous silicon layer over the substrate including a pair of first regions, a second region disposed between the pair of first regions, and at least one third region, each of which being disposed between and contiguous with the second region and each of the pair of first regions, the second region including a sub-region contiguous with each of the at least one third region, forming a heat retaining layer over the substrate, irradiating the patterned amorphous silicon layer with a laser through the heat retaining layer to form a patterned crystallized silicon layer corresponding to the patterned amorphous silicon layer including a grain boundary extending substantially across a crystallized sub-region corresponding to the sub-region, and forming a patterned conductive layer over a portion of a crystallized second region of the patterned crystallized silicon layer corresponding to the second region of the patterned amorphous silicon layer.

Also in accordance with the present invention, there is provided a method for fabricating a thin film transistor (“TFT”) device that comprises providing a substrate, forming a first and a second patterned amorphous silicon regions over the substrate, each of the first and the second patterned amorphous silicon regions including a pair of first regions, a second region disposed between the first regions, and at least one third region, each of which being disposed between and contiguous with the second region and one of the pair of first regions, the second region including a sub-region contiguous with each of the at least one third region, forming a heat retaining layer over the substrate, irradiating the first and the second patterned amorphous silicon regions with a laser through the heat retaining layer to form a first and a second patterned crystallized silicon regions corresponding to the first and the second patterned amorphous silicon regions, each of the first and the second patterned crystallized silicon regions including a grain boundary extending substantially across a crystallized sub-region corresponding to the sub-region of each of the patterned amorphous silicon regions, forming a first doped region corresponding to the pair of first regions, the at least one third region and portions of the sub-region of the first patterned amorphous silicon region, the first doped region having an impurity of a first type and a first density, forming a patterned conductive layer over a region corresponding to a portion of the second region of each of the first and the second patterned amorphous silicon regions, forming a second and a third doped regions corresponding to the first and the second patterned crystallized silicon regions, respectively, the second and the third doped regions having an impurity of the first type and a second density smaller than the first density, forming a fourth doped region corresponding to the second doped region except a region corresponding to the first doped region and the sub-region of the first patterned amorphous silicon region, the fourth doped region having an impurity of a second type, and forming a fifth doped region corresponding to the pair of first regions, the at least one third region and the sub-region of the second patterned amorphous silicon region, the fifth doped region having an impurity of the second type.

Further in accordance with the present invention, there is provided a method for fabricating a thin film transistor (“TFT”) device that comprises providing a substrate, forming an amorphous silicon layer over the substrate, patterning the amorphous silicon layer to form a first region, a second region, a third region disposed between the first and the second regions, at least one fourth region disposed between and contiguous with the first and the third regions, and at least one fifth region disposed between and contiguous with the second and third regions, the third region including a sub-region contiguous with the at least one fourth and at least one fifth regions, forming a heat retaining layer over the substrate, and crystallizing the third region through the heat retaining layer to form a crystallized region including a grain boundary extending substantially across a crystallized sub-region corresponding to the sub-region of the third region.

Still in accordance with the present invention, there is provided a method for fabricating a thin film transistor (“TFT”) device that comprises providing a substrate, forming an amorphous silicon layer over the substrate, patterning the amorphous silicon layer to form a first region, a second region and a third region disposed between the first and the second regions, each of the first and the second regions including at least one elongated portion contiguous with the third region to define a sub-region in the third region, forming a heat retaining layer over the substrate, and crystallizing the third region through the heat retaining layer to form a crystallized region including a grain boundary extending substantially across a crystallized sub-region corresponding to the sub-region in the third region.

Yet still in accordance with the present invention, there is provided a method for fabricating a thin film transistor (“TFT”) device that comprises providing a substrate, forming an amorphous silicon layer over the substrate, patterning the amorphous silicon layer to form a first and a second patterned regions, each of the first and the second patterned regions including a first region, a second region and a third region disposed between the first and the second regions, each of the first and the second regions including at least one elongated portion contiguous with the third region to define a sub-region in the third region, forming a heat retaining layer over the substrate, and crystallizing the first and the second patterned regions through the heat retaining layer to form a first and a second crystallized regions, each of the first and second crystallized regions including a grain boundary extending substantially across a crystallized sub-region corresponding to the sub-region of each of the first and the second patterned regions.

Additional features and advantages of the present invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIGS. 1A to 1D are diagrams illustrating a method for fabricating a thin film transistor (“TFT”) device in accordance with one embodiment of the present invention;

FIG. 2 is a diagram of a TFT device in accordance with one embodiment of the present invention;

FIGS. 3A to 3E are diagrams illustrating a method for fabricating a TFT device in accordance with another embodiment of the present invention;

FIGS. 4A to 4D are diagrams illustrating a method for fabricating a TFT device in accordance with still another embodiment of the present invention; and

FIGS. 5A to 5D are diagrams illustrating a method for fabricating a TFT device in accordance with yet another embodiment of the present invention.

### DETAILED DESCRIPTION OF THE INVENTION

Reference will now be made in detail to the present embodiments of the invention, examples of which are illustrated in the accompanying drawings. Wherever possible, the same reference numbers will be used throughout the drawings to refer to the same or like parts.

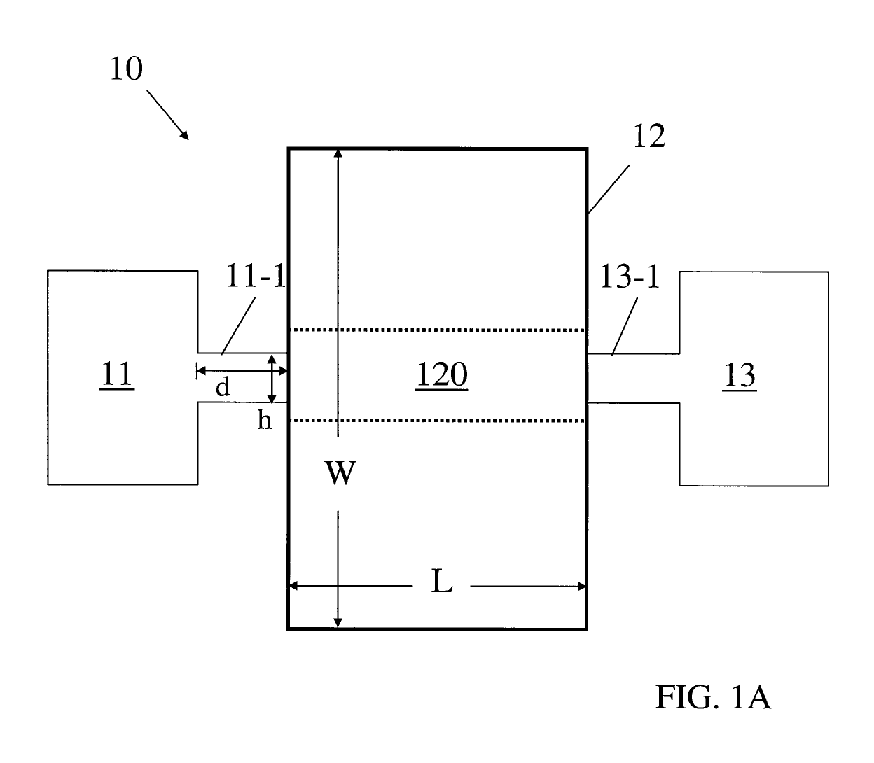

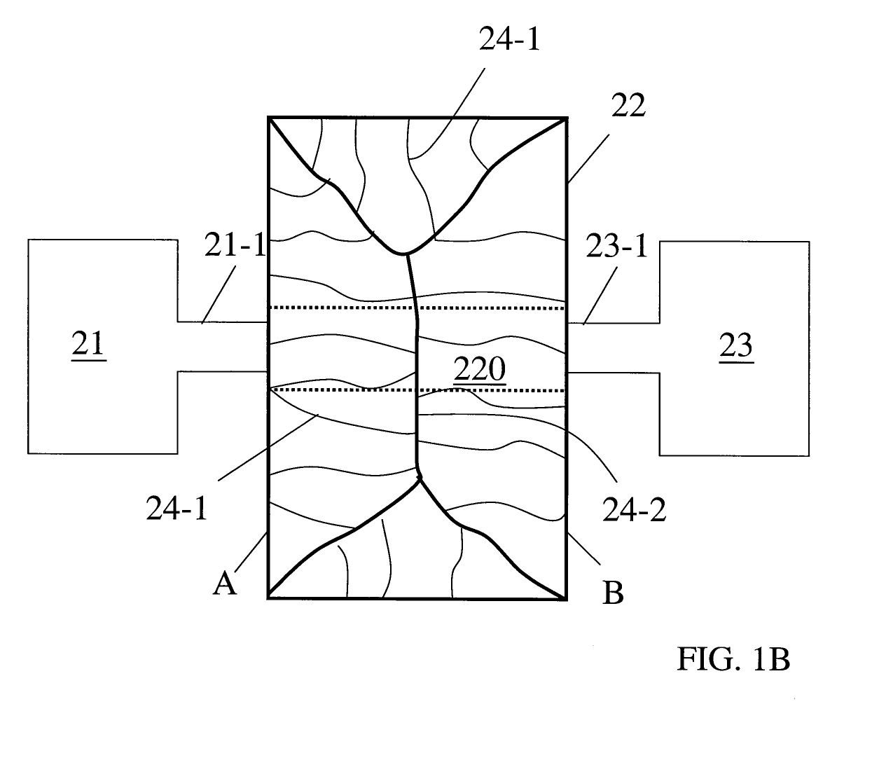

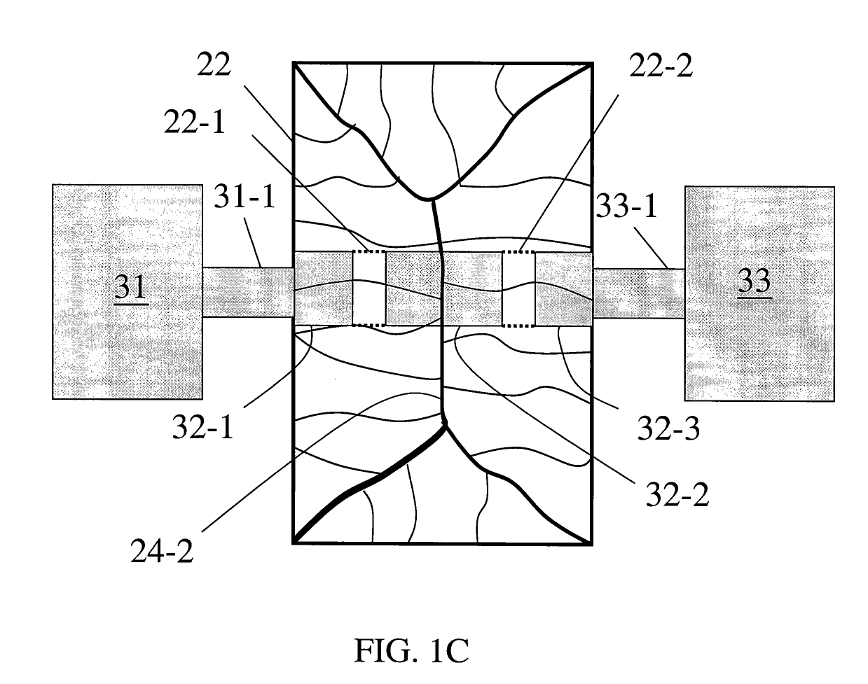

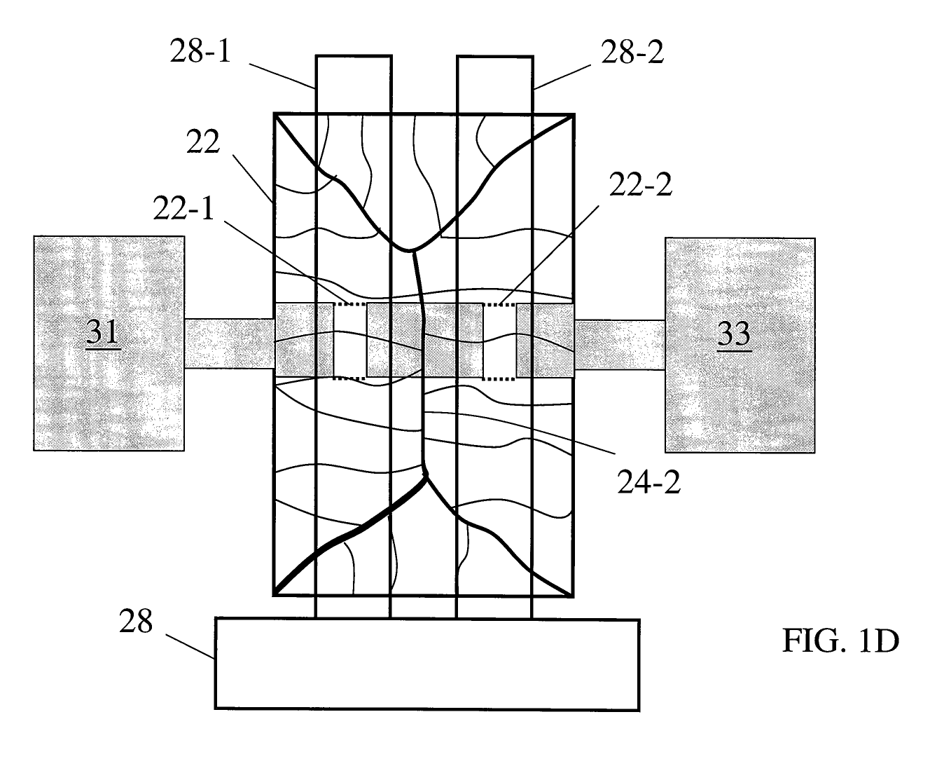

FIGS. 1A to 1D are diagrams illustrating a method for fabricating a thin film transistor (“TFT”) in accordance with one embodiment of the present invention. Referring to FIG. 1A, a patterned amorphous silicon layer 10 is formed over a substrate (not shown) by forming a layer of amorphous silicon over the substrate by a conventional plasma enhanced chemical vapor deposition (“PECVD”) process, a conventional physical vapor deposition (“PVD”) process or other suitable process, followed by a conventional patterning and etching process. The substrate, made of such as glass or resin, has a thickness ranging from approximately 0.2 to 0.6 mm (millimeter) but the thickness could vary in particular applications. The patterned amorphous silicon layer 10 includes a pair of first regions 11 and 13, and a second region 12 disposed between the pair of first regions 11 and 13. The pair of first regions 11 and 13 include bridges 11-1 and 13-1, respectively, and are contiguous with the second region 12 at the bridges 11-1 and 13-1. The pair of first regions 11 and 13 eventually become a part of a source region or a part of a drain region of a TFT device, while the second region 12 defines therein an active region 120 contiguous with the bridges 11-1 and 13-1 for the TFT device. The patterned amorphous silicon layer 10 has a thickness of approximately 500 Å (angstrom). To facilitate control of a vertical grain boundary, which will be later discussed, the second region 12 has a width W greater than a length L thereof. Each of the bridges 11-1 and 13-1 is formed in an elongated region having a width h smaller than a length d thereof.

Optionally, a buffer layer (not shown) may be formed on the substrate prior to the formation of the patterned amorphous silicon layer 10. The buffer layer such as a silicon dioxide (SiO₂) film functions to prevent metal ions in the substrate from contaminating subsequent layers formed over the substrate. The buffer layer has a thickness of approximately 1000 Å. The patterned amorphous silicon layer 10 is then de-hydrated by, for example, a dehydration bake conducted in a vacuum oven at approximately 450° C. for 2 hours, or a rapid thermal process (“RTP”)

Next, a heat retaining layer (not shown) is formed on the patterned amorphous silicon layer 10 by, for example, a conventional CVD process. The heat retaining layer refers to one made of a material that absorbs a portion of an irradiating beam and transmits the remaining portion. The heat retaining layer and the use of a heat retaining layer to control a vertical grain boundary have been discussed in U.S. patent application Ser. No. 11/226,679 (the '679 application), entitled “Method of Semiconductor Thin Film Crystallization and Semiconductor Device Fabrication”, filed Sep. 14, 2005 by Jia-Xing Lin et al., who is one of the inventors of the present invention. The '679 application is herein incorporated by reference. In one embodiment according to the present invention, the heat retaining layer includes silicon oxynitride, which absorbs 30% of an irradiating beam. The retaining layer has a thickness of approximately 2000 to 5000 Å.

Next, referring to FIG. 1B, a pair of crystallized first regions 21, 23, crystallized bridges 21-1, 23-1 and a crystallized second region 22 are formed by, for example, a conventional excimer laser process or other suitable process. In one embodiment according to the present invention, the first regions 11, 13, bridges 11-1, 13-1 and second region 12 of the patterned amorphous silicon layer 10 are crystallized by irradiation with a laser through the heat retaining layer. A crystallized active region 220 corresponding to the crystallized bridges 21-1 and 21-3 is defined in the crystallized second region 22. Suitable laser sources include but are not limited to frequency-doubled solid state laser beams such as Nd:YAG laser beams with a wavelength of approximately 532 nm (nanometer), Nd:YVO4 laser beams with a wavelength of approximately 532 nm and Nd:YLF laser beams with a wavelength of approximately 527 nm, and excimer laser beams such as xenon chloride (XeCl) laser beams with a wavelength of approximately 308 nm (nanometer) and krypton fluoride (KrF) laser beams with a wavelength of approximately 248 nm. The laser source provides the necessary energy to melt the second region 12 underlying the heat retaining layer. Nucleation and crystalline growth commences from the initial nucleation sites A and B via lateral growth. In the lateral growth, a portion where a semiconductor is melted completely due to the irradiation of a laser beam, and a portion where the solid-phase semiconductor area remains, are formed, and then, the crystal growth begins around the solid-phase semiconductor area as the crystal nucleus. Since it takes a certain period of time for nucleation to take place in the completely melted area, during the period of time until the nucleation takes place in the completely melted area, the crystal grows around the above-described solid-phase semiconductor area as the crystal nucleus in the horizontal or lateral direction with respect to the film surface of the above-described semiconductor. Therefore, the crystal grain grows up to a length as long as several tens of times of the film thickness.

The crystallized second region 22 serves as an active layer for the TFT device. Grain boundaries including a main grain boundary 24-1 and sub-boundaries 24-2 are formed in the crystallized second region 22 during the nucleation and crystal growth. In particular, the grain boundary 24-2 extending in a direction in parallel with the initial nucleation site A or B and substantially across the crystallized active region 220 of the TFT device is expected to be formed at a center region between the sites A and B. A grain boundary of a crystal grain refers to an area where the translational symmetry of the crystal is decayed. It is known that, due to the influence of the recombination center or trapping center of the carrier, or the influence of the potential barrier in the crystal grain boundary caused from the crystal defect or the like, the current transport characteristics of the carrier is decreased, and as a result, the OFF-current increases in the TFT. For example, the grain boundary 24-2 may adversely affect the mobility of carriers, which move across the center region during current transport. The length of the grain boundary 24-2 is determined by the length L and width W of the second region 12. Generally, the greater the value of W/L, the longer the grain boundary 24-2.

After the process of crystallization, the heat retaining layer is removed by, for example, a conventional etching process using a mixture of hydrofluoric acid (HF) and ammonium fluoride NH₃F. An insulating layer (not shown) is then formed over the crystallized second region 22 by, for example, a conventional PECVD process or other suitable process. Suitable materials for the insulating layer include silicon nitride, silicon oxide and silicon oxynitride. The thickness of the insulating layer ranges from approximately 700 to 4000 Å. Alternatively, if provided with desired dielectric property, the heat retaining layer is retained to serve as an insulating layer after the process of crystallization. Furthermore, alternatively, a portion of the heat retaining layer is retained to serve as an insulating layer for the TFT device, while the other portion of the heat retaining layer is removed.

Next, referring to FIG. 1C, a pair of doped first regions 31, 33, doped bridges 31-1, 33-1, and doped regions 32-1, 32-2 and 32-3 in the crystallized active region 220 are formed by doping one of an n-type impurity such as phosphor or a p-type impurity such as boron into the pair of first crystallized regions 21, 23, crystallized bridges 21-1, 23-1, and portions of the crystallized active region 220 by, for example, a conventional ion implanting process or other suitable process. The doped region 32-2, which overlaps the grain boundary 24-2, is disposed between the doped regions 32-1 and 32-3, which are in turn contiguous with the doped bridges 31-1 and 33-1, respectively. A first channel region 22-1 in the crystallized active region 220 is defined between the doped regions 32-1 and 32-2. A second channel region 22-2 in the crystallized active region 220 is defined between the doped regions 32-2 and 32-3. Since the grain boundary 24-2 does not extend across the first and second channel regions 22-1 and 22-2, the carrier mobility is not adversely affected.

Next, referring to FIG. 1D, a gate structure 28 including a first gate finger 28-1 and a second gate finger 28-2 is formed over the crystallized second region 22 by forming a metal layer in a conventional PVD process followed by a conventional patterning and etching process. The first and second gate fingers 28-1 and 28-2 overlap the first and second channel regions 22-1 and 22-2, respectively. Suitable materials for the gate structure 28 include but are not limited to TiAlTi, MoAlMo, CrAlCr, MoW, Cr and Cu. The thickness of the gate structure 28 ranges from approximately 1000 to 3000 Å but could be other thickness.

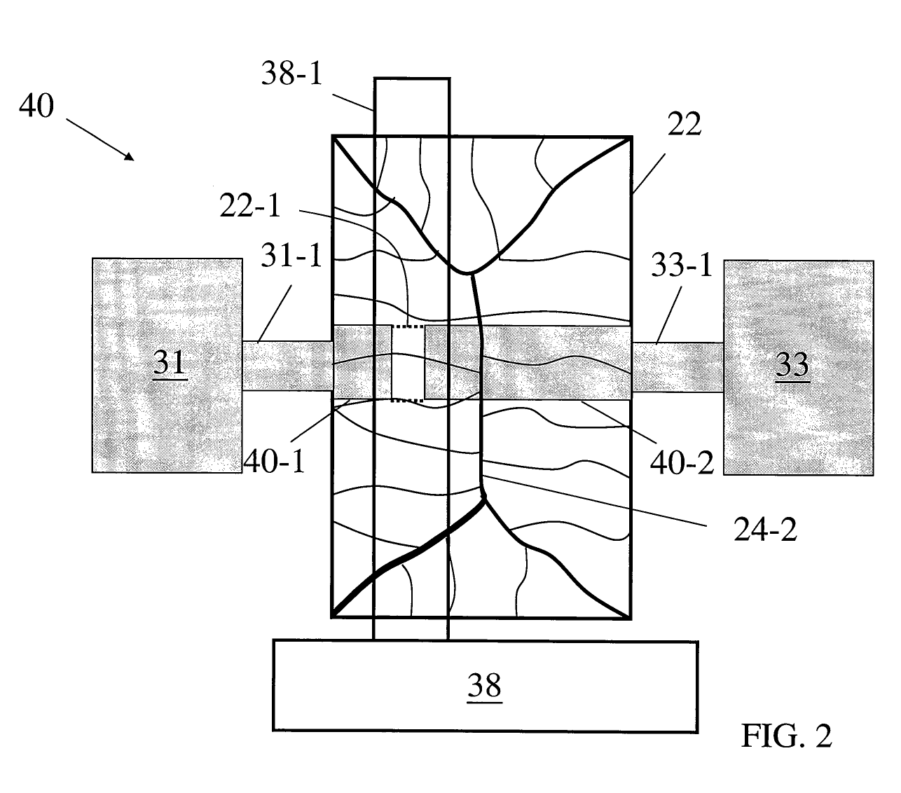

FIG. 2 is a diagram of a TFT device 40 in accordance with one embodiment of the present invention. Unlike the dual-gate structure illustrated in FIG. 1D, the TFT device 40 includes a single-gate structure. Referring to FIG. 2, the TFT device 40 includes a similar structure to the TFT device illustrated in FIG. 1D except a first doped region 40-1, a second doped region 40-2 and a gate structure 38. The first doped region 40-1 is contiguous with the doped bridge 31-1. The second doped region 40-2 is contiguous with the doped bridge 33-1 and extends across the grain boundary 24-2. The channel region 22-1 is defined between the doped regions 40-1 and 40-2. The gate structure 38 includes a gate 38-1 overlapping the channel region 22-1. Skilled persons in the art will realize that, in addition to the dual-gate structure illustrated in FIG. 1D and the single-gate structure illustrated in FIG. 2, a multiple-gate structure may be achieved in accordance with the method of the present invention.

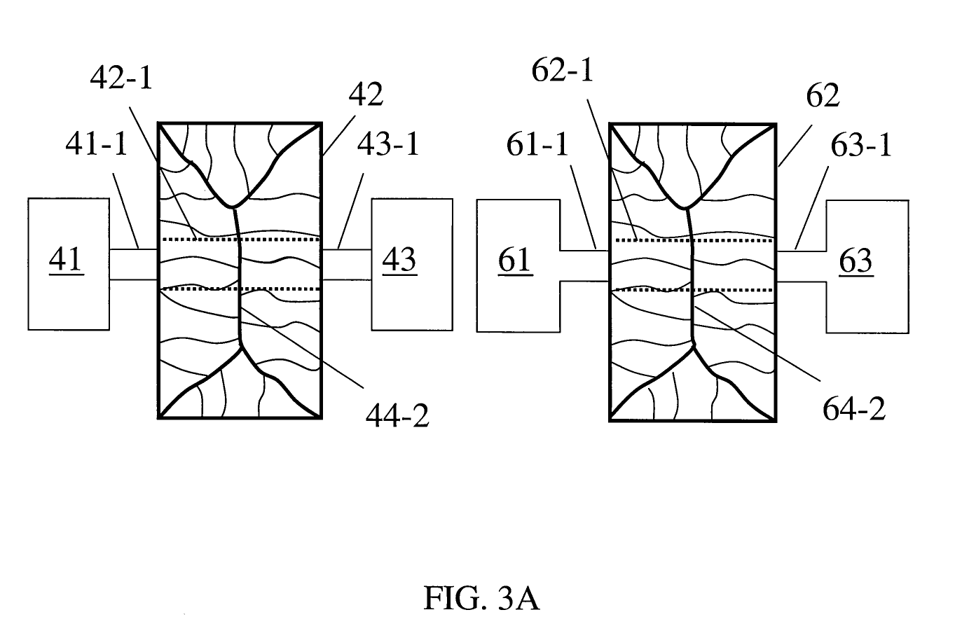

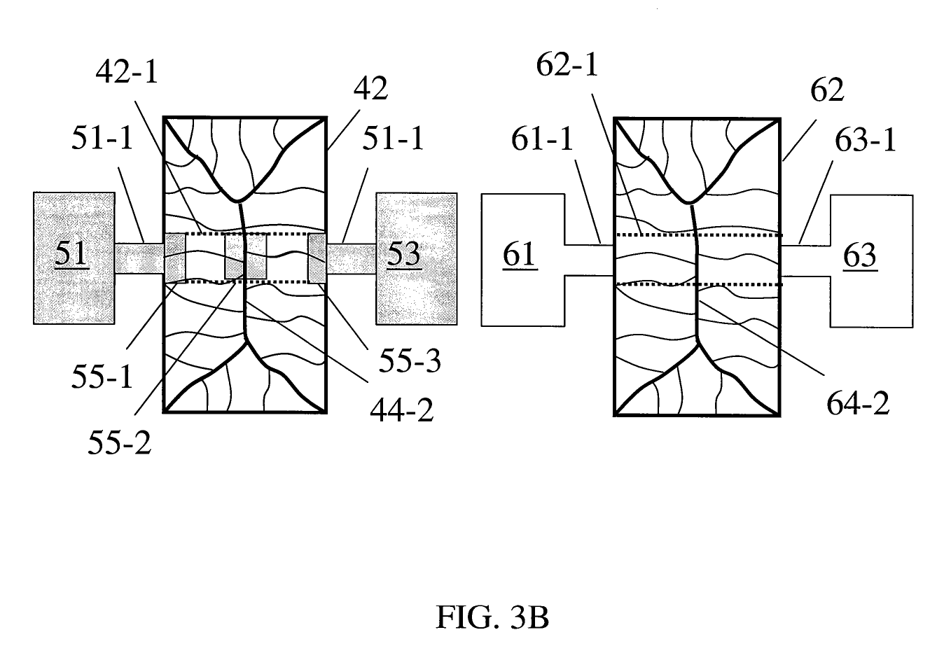

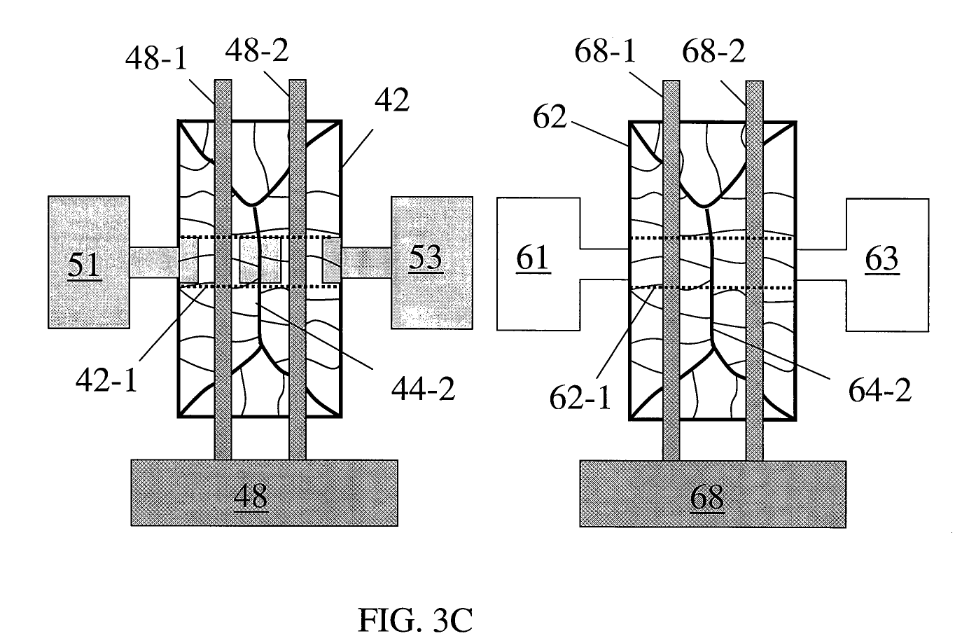

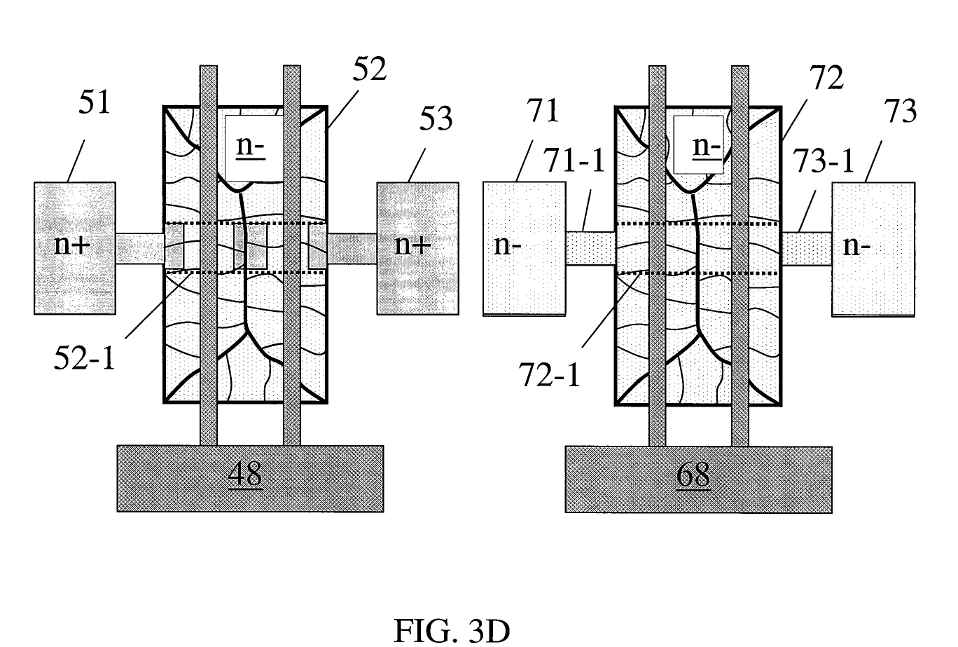

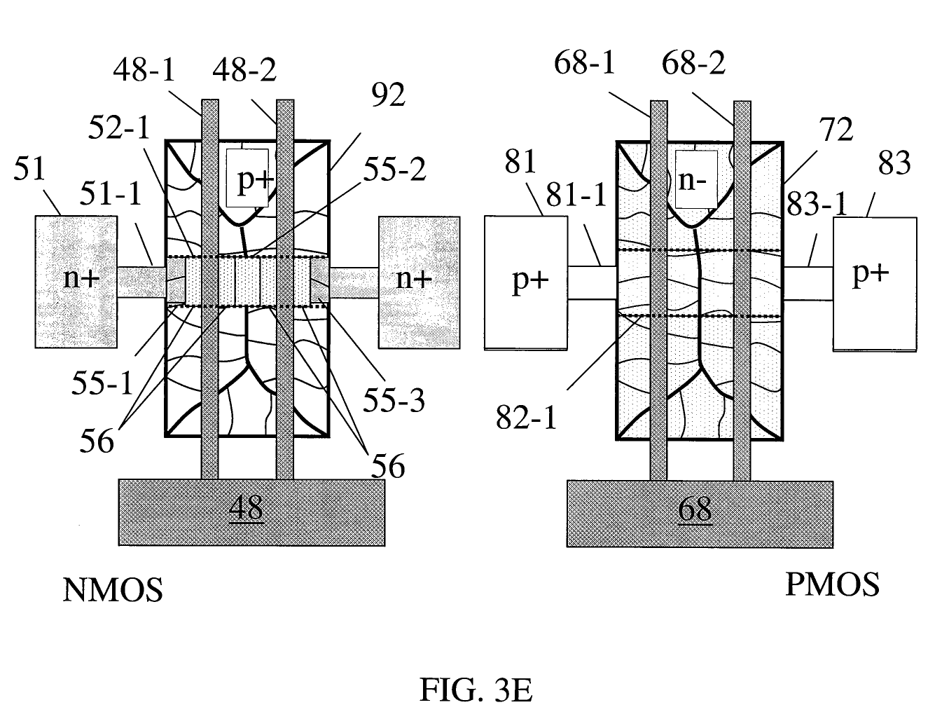

FIGS. 3A to 3E are diagrams illustrating a method for fabricating a TFT device in accordance with another embodiment of the present invention. Referring to FIG. 3A, a first crystallized region 42 and a second crystallized region 62 are formed over a substrate (not shown) by a process similar to that previously discussed by reference to FIGS. 1A and 1B. The first crystallized region 42 is disposed between a pair of crystallized third regions 41 and 43, and the second crystallized region 62 is disposed between a pair of crystallized fourth regions 61 and 63. The pair of crystallized third regions 41 and 43 include crystallized bridges 41-1 and 43-1, respectively, which are contiguous with the first crystallized region 42. The pair of crystallized fourth regions 61 and 63 include crystallized bridges 61-1 and 63-1, respectively, which are contiguous with the second crystallized region 62. Furthermore, a first crystallized active region 42-1, extending across a grain boundary 44-2, is defined in the first crystallized region 42. A second crystallized active region 62-1, extending across a grain boundary 64-2, is defined in the second crystallized region 62.

Referring to FIG. 3B, a pair of doped third regions 51 and 53 including respectively doped bridges 51-1 and 53-1, and doped regions 55-1, 55-2 and 55-3 in the first crystallized region 42 are formed by doping an n-type impurity such as phosphor into the pair of crystallized third regions 41 and 43, crystallized bridges 41-1 and 43-1, and portions of the first crystallized active region 42-1 shown in FIG. 3A by, for example, a conventional ion implanting process followed by an annealing process to form heavily n-doped (n+) layers. The doped region 55-2, which overlaps the grain boundary 44-2, is disposed between the doped regions 55-1 and 55-3, which are in turn contiguous with the doped bridges 51-1 and 53-1, respectively. The impurity density of the n+ doped regions ranges from approximately 8×10¹⁴ to 5×10¹⁵ cm⁻².

An insulating layer (not shown) is then formed over the substrate by, for example, a conventional PECVD process or other suitable process. Alternatively, a heat retaining layer used in the process of crystallization is retained to serve as the insulating layer. Next, referring to FIG. 3C, a first gate structure 48 and a second gate structure 68 are formed by forming a metal layer on the insulating layer by a conventional PVD process followed by a conventional patterning and etching process. The first gate structure 48 includes a first gate finger 48-1 and a second gate finger 48-2, which extend across the first crystallized active region 42-1. Likewise, the second gate structure 68 includes a first gate finger 68-1 and a second gate finger 68-2, which extend across the second crystallized active region 62-1.

Referring to FIG. 3D, a pair of doped fourth regions 71 and 73 including respectively doped bridges 71-1 and 73-1, a doped first region 52 and a doped second region 72 are formed by doping an n-type impurity over the substrate by, for example, a conventional ion implanting process followed by an annealing process to form lightly n-doped (n−) layers. The ion implant is blocked by the gate finger structures 48 and 68 such that regions under the gate structures 48 and 68 are undoped. Specifically, a first active region 52-1 in the doped first region includes channel regions (not numbered), which are undoped, and a second active region 72-1 in the doped second region includes channel regions (not numbered), which are undoped. The impurity density of the lightly n-doped regions ranges from approximately 10¹³ to 5×10¹⁴ cm⁻².

Next, referring to FIG. 3E, a pair of doped fourth regions 81 and 83 including respectively doped bridges 81-1 and 83-1, a doped second active region 82-1, and a doped region 92 are formed by doping a p-type impurity such as boron into the pair of lightly n-doped (n−) fourth doped regions 71 and 73, doped bridges 71-1 and 73-1, the second active region 72-1 and the doped region 52 except the first active region 52-1 illustrated in FIG. 3D by, for example, a conventional ion implanting process followed by an annealing process to form heavily p-doped (p+) layers. The ion implant is blocked by the gate finger structures 48 and 68 such that the regions (not numbered) in the active regions 52-1 and 82-1 under the gate fingers 48-1, 48-2, 68-1 and 68-2 eventually become channel regions for an NMOS (n-type metal-oxide-semiconductor) and PMOS (p-type metal-oxide-semiconductor) TFT devices. Since the doped region 55-1, previously lightly n-doped, is not p-doped, regions 56 become lightly doped drain (“LDD”) regions for the NMOS TFT device. The impurity density of the p-doped regions ranges from approximately 8×10¹⁴ to 5×10¹⁵ cm⁻².

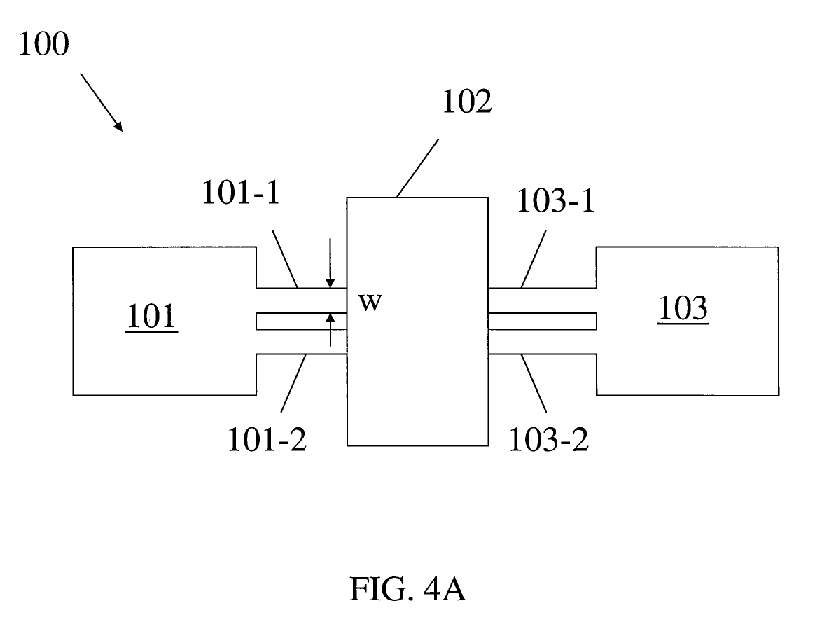

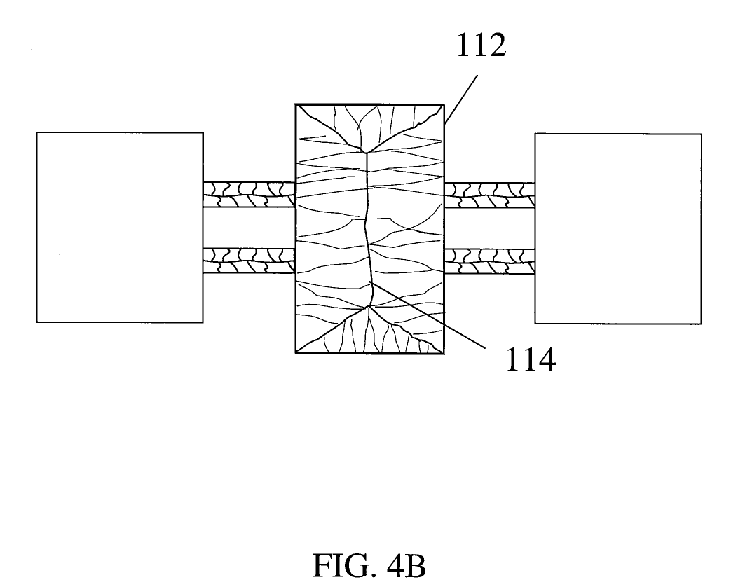

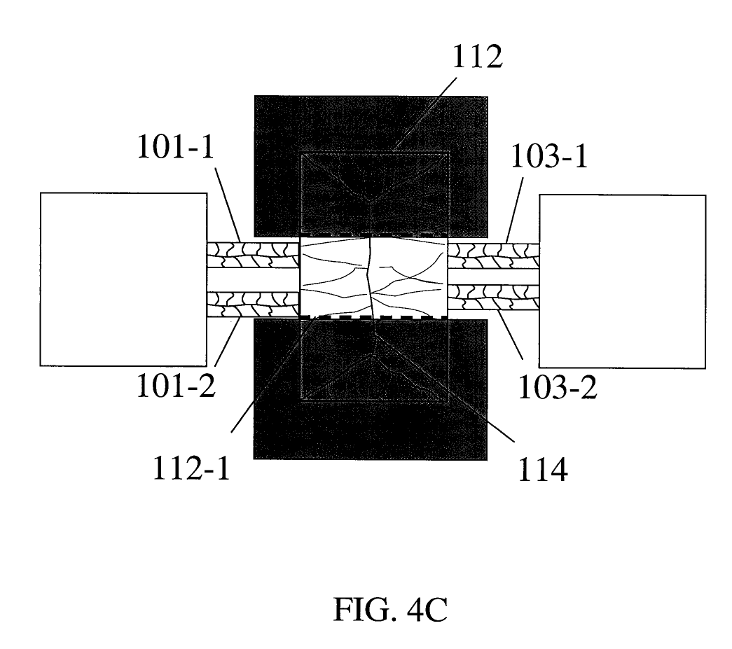

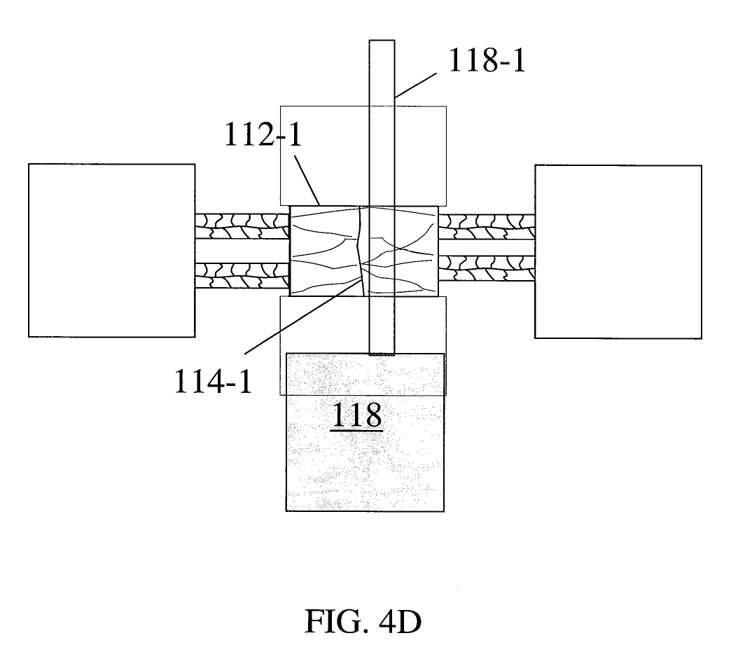

FIGS. 4A to 4D are diagrams illustrating a method for fabricating a TFT in accordance with still another embodiment of the present invention. Referring to FIG. 4A, a patterned amorphous silicon layer 100 is formed over a substrate (not shown) by forming a layer of amorphous silicon over the substrate by, for example, a conventional PECVD process followed by a conventional patterning and etching process. The patterned amorphous silicon layer 100 includes a pair of first regions 101 and 103, and a second region 102 disposed between the pair of first regions 101 and 103. The first region 101 includes bridges 101-1 and 101-2, which are contiguous with the second region 102. Likewise, the first region 103 includes bridges 103-1 and 103-2, which are contiguous with the second region 102. As compared to the patterned amorphous silicon layer 10 illustrated in FIG. 1A, the patterned amorphous silicon layer 100 includes two bridges between one of the first regions 101 and 103 and the second region 102. Each of the two bridges, for example, bridges 101-1 and 101-2, has a smaller width w than that of the bridge 11-1, given the same device size. It is believed that an edge effect occurs due to grain boundaries formed in a bridge may be alleviated if the bridge is designed with a smaller width. The edge effect may adversely affect the grain distribution in the active region, and in turn the desired electric property of a TFT device.

Next, referring to FIG. 4B, a crystallized region 112 is formed over the substrate by a process similar to that previously discussed by reference to FIGS. 1A and 1B. A grain boundary 114 extending substantially at a center part of the crystallized region 112 is formed under the control of a heat retaining layer.

Referring to FIG. 4C, to further alleviate the edge effect caused by the bridges 101-1, 101-2, 103-1 and 103-2, the crystallized region 112 except an active region 112-1 defined therein is removed by a conventional patterning and etching process. Subsequently, referring to FIG. 4D, a gate structure 118 including a gate finger 118-1 is formed over the active region 112-1. The gate finger 118-1 may be disposed to either not cover, as illustrated in the present embodiment, or cover a remaining grain boundary 114-1. A channel region (not numbered) is defined in the active region 112-1 under the gate finger 118-1. Next, a source region and a drain region are formed in a conventional ion implanting process.

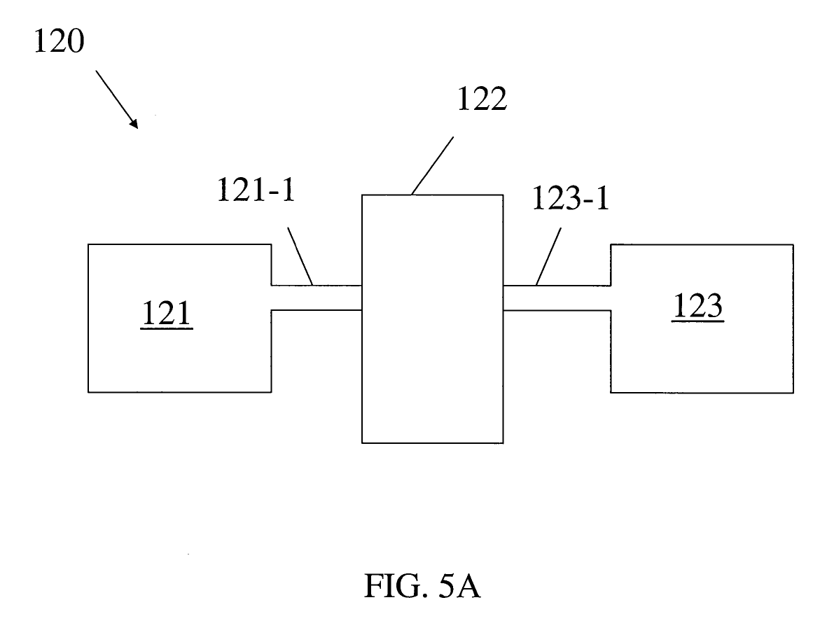

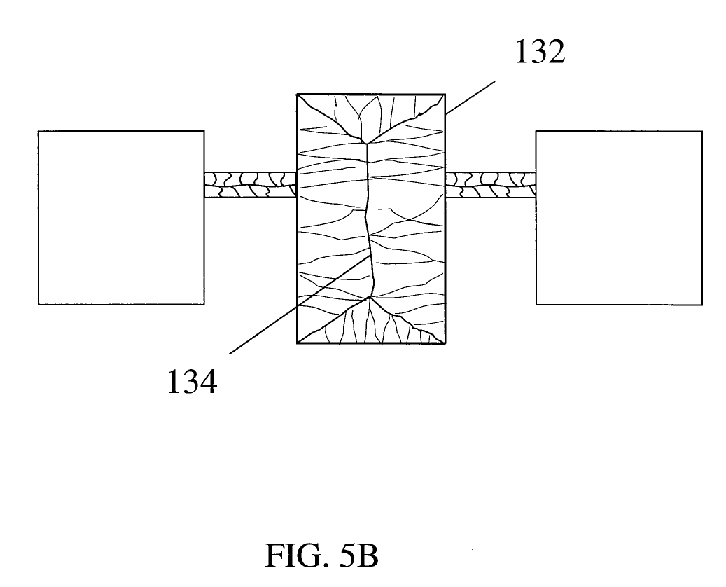

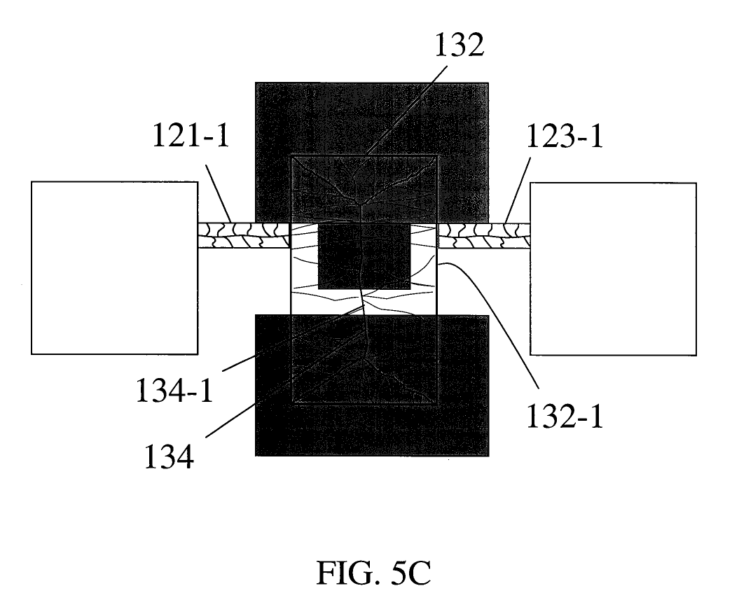

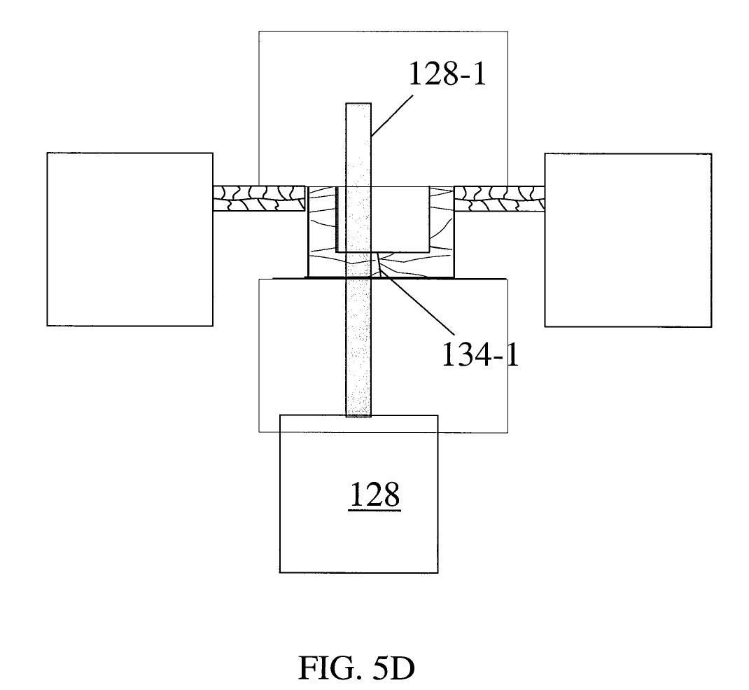

FIGS. 5A to 5D are diagrams illustrating a method for fabricating a TFT device in accordance with yet another embodiment of the present invention. Referring to FIG. 5A, a patterned amorphous silicon layer 120 is formed over a substrate (not shown) by forming a layer of amorphous silicon over the substrate by a conventional PECVD process followed by a conventional patterning and etching process. The patterned amorphous silicon layer 120 includes a pair of first regions 121 and 123, and a second region 122 disposed between the pair of first regions 121 and 123. The first region 121 includes a bridge 121-1, which is contiguous with the second region 122. Likewise, the first region 123 includes a bridge 123-1, which is contiguous with the second region 122.

Next, referring to FIG. 5B, a crystallized region 132 is formed over the substrate by a process similar to that previously discussed by reference to FIGS. 1A and 1B. A grain boundary 134 extending substantially at a center portion of the crystallized region 132 is formed under the control of a heat retaining layer.

Referring to FIG. 5C, to further alleviate the edge effect caused by the bridges 121-1 and 123-1, the crystallized region 132 except a U-shaped active region 132-1 defined therein is removed by a conventional patterning and etching process. The active region 132-1 winds from the bridge 121-1 to the bridge 123-1. Subsequently, referring to FIG. 5D, a gate structure 128 including a gate finger 128-1 is formed over the active region 132-1. The gate finger 128-1 may be disposed to either not cover, as illustrated in the present embodiment, or cover a remaining grain boundary 134-1. A channel region (not numbered) is thereby defined in the active region 132-1 under the gate finger 128-1. Next, a source region and a drain region are formed in a conventional ion implanting process.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

I/we claim:

1. A method for fabricating a thin film transistor (“TFT”) device, comprising:
providing a substrate;
forming a patterned amorphous silicon layer over the substrate including a pair of first regions, a second region disposed between the pair of first regions, and at least one third region, each of which being disposed between and contiguous with the second region and each of the pair of first regions, the second region including a sub-region contiguous with each of the at least one third region;
forming a heat retaining layer over the substrate;
irradiating the patterned amorphous silicon layer through the heat retaining layer to form a patterned crystallized silicon layer corresponding to the patterned amorphous silicon layer including a grain boundary extending substantially across a crystallized sub-region corresponding to the sub-region; and
forming a patterned conductive layer over a portion of a crystallized second region of the patterned crystallized silicon layer corresponding to the second region of the patterned amorphous silicon layer.

2. The method of claim 1, further comprising removing the crystallized second region except the crystallized sub-region.

3. The method of claim 1, further comprising patterning the crystallized second region to form a winding crystallized region.

4. The method of claim 1, further comprising forming the patterned conductive layer including at least one elongated portion extending over the crystallized second region.

5. The method of claim 1, further comprising doping the patterned crystallized silicon layer after forming the patterned conductive layer.

6. The method of claim 1, further comprising doping the patterned crystallized silicon layer before forming the patterned conductive layer.

7. The method of claim 1, further comprising retaining the heat retaining layer to serve as an insulating layer after forming the patterned crystallized silicon layer.

8. The method of claim 1, further comprising:
removing the heat retaining layer; and
forming an insulating layer over the patterned crystallized silicon layer.

9. A method for fabricating a thin film transistor (“TFT”) device, comprising:
providing a substrate;
forming a first and a second patterned amorphous silicon regions over the substrate, each of the first and the second patterned amorphous silicon regions including a pair of first regions, a second region disposed between the first regions, and at least one third region, each of which being disposed between and contiguous with the second region and one of the pair of first regions, the second region including a sub-region contiguous with each of the at least one third region;
forming a heat retaining layer over the substrate;
irradiating the first and the second patterned amorphous silicon regions through the heat retaining layer to form a first and a second patterned crystallized silicon regions corresponding to the first and the second patterned amorphous silicon regions, each of the first and the second patterned crystallized silicon regions including a grain boundary extending substantially across a crystallized sub-region corresponding to the sub-region of each of the patterned amorphous silicon regions;
forming a first doped region corresponding to the pair of first regions, the at least one third region and portions of the sub-region of the first patterned amorphous silicon region, the first doped region having an impurity of a first type and a first density;
forming a patterned conductive layer over a region corresponding to a portion of the second region of each of the first and the second patterned amorphous silicon regions;
forming a second and a third doped regions corresponding to the first and the second patterned crystallized silicon regions, respectively, the second and the third doped regions having an impurity of the first type and a second density smaller than the first density;
forming a fourth doped region corresponding to the second doped region except a region corresponding to the first doped region and the sub-region of the first patterned amorphous silicon region, the fourth doped region having an impurity of a second type; and
forming a fifth doped region corresponding to the pair of first regions, the at least one third region and the sub-region of the second patterned amorphous silicon region, the fifth doped region having an impurity of the second type.

10. The method of claim 9, further comprising forming a patterned conductive layer including at least one elongated portion to overlap a region corresponding to the sub-region of each of the first and the second patterned amorphous silicon regions.

11. The method of claim 9, further comprising removing a region corresponding to the second region except the sub-region of at least one of the first and the second patterned amorphous silicon regions.

12. The method of claim 9, further comprising patterning a region corresponding to the second region of at least one of the first and the second patterned amorphous silicon regions to form a winding path.

13. The method of claim 9, further comprising retaining the heat retaining layer to serve as an insulating layer after forming the first and the second patterned crystallized silicon regions.

14. The method of claim 9, further comprising:
removing the heat retaining layer; and
forming an insulating layer over the first and the second patterned crystallized silicon regions.

15. A method for fabricating a thin film transistor (“TFT”) device, comprising:
providing a substrate;
forming an amorphous silicon layer over the substrate;
patterning the amorphous silicon layer to form a first region, a second region, a third region disposed between the first and the second regions, at least one fourth region disposed between and contiguous with the first and third regions, and at least one fifth region disposed between and contiguous with the second and the third regions, the third region including a sub-region contiguous with the at least one fourth and at least one fifth regions;
forming a heat retaining layer over the substrate; and
crystallizing the third region through the heat retaining layer to form a crystallized region including a grain boundary extending substantially across a crystallized sub-region corresponding to the sub-region of the third region.

16. The method of claim 15, further comprising doping portions of the crystallized sub-region.

17. The method of claim 16, further comprising forming a patterned conductive layer over the third region.

18. The method of claim 15, further comprising forming a patterned conductive layer over the third region without overlapping the grain boundary.

19. The method of claim 15, further comprising retaining the heat retaining layer to serve as an insulating layer.

20. The method of claim 15, further comprising:
removing the heat retaining layer; and
forming an insulating layer over the crystallized region.

21. The method of claim 15, further comprising removing the crystallized region except the crystallized sub-region.

22. The method of claim 15, further comprising patterning the crystallized region to form a winding path corresponding to a region extending from one of the at least one fourth region to one of the at least one fifth region.

23. A method for fabricating a thin film transistor (“TFT”) device, comprising:
providing a substrate;
forming an amorphous silicon layer over the substrate;
patterning the amorphous silicon layer to form a first region, a second region and a third region disposed between the first and the second regions, each of the first and the second regions including at least one elongated portion contiguous with the third region to define a sub-region in the third region;
forming a heat retaining layer over the substrate; and
crystallizing the third region through the heat retaining layer to form a crystallized region including a grain boundary extending substantially across a crystallized sub-region corresponding to the sub-region in the third region.

24. The method of claim 23, further comprising doping portions of the crystallized sub-region, leaving at least one undoped portion in the crystallized sub-region.

25. The method of claim 24, further comprising forming a patterned conductive layer over the third region to overlap the at least one undoped portion in the crystallized sub-region.

26. The method of claim 23, further comprising patterning the crystallized region to form a winding path corresponding to a region extending from one of the at least one elongated portion of the first region to one of the at least one elongated portion of the second region.

27. The method of claim 23, further comprising removing the crystallized region except the crystallized sub-region.

28. A method for fabricating a thin film transistor (“TFT”) device, comprising:
providing a substrate;
forming an amorphous silicon layer over the substrate;
patterning the amorphous silicon layer to form a first and a second patterned regions, each of the first and the second patterned regions including a first region, a second region and a third region disposed between the first and the second regions, each of the first and the second regions including at least one elongated portion contiguous with the third region to define a sub-region in the third region;
forming a heat retaining layer over the substrate; and
crystallizing the first and the second patterned regions through the heat retaining layer to form a first and a second crystallized regions, each of the first and the second crystallized regions including a grain boundary extending substantially across a crystallized sub-region corresponding to the sub-region of each of the first and the second patterned regions.

29. The method of claim 28, further comprising:
doping portions of the crystallized sub-region of the first crystallized region with an impurity of a first type having a first density; and
forming a patterned conductive layer over the third region of each of the first and the second patterned regions.

30. The method of claim 29, further comprising:
doping the first and the second crystallized regions with an impurity of the first type having a second density smaller than the first density;
doping a region corresponding to the first crystallized region except the crystallized sub-region of the first crystallized region with an impurity of a second type; and
doping a region corresponding to the first and the second regions and the sub-region of the second patterned region with an impurity of the second type.

31. The method of claim 28, further comprising forming a patterned conductive layer including at least one elongated portion to overlap at least one undoped portion in the crystallized sub-region of the first crystallized region.

32. The method of claim 28, further comprising removing one of the first and the second crystallized regions except the crystallized sub-region of one of the first and the second crystallized regions.

33. The method of claim 28, further comprising patterning one of the first and crystallized regions to form a winding path in a region corresponding to the third region.
